(19) United States
(12) Patent Application Publication
(10) Pub. No.: US 2007/0041591 A1
(43) Pub. Date: Feb. 22, 2007

(54) Audio player

(76) Inventors: Seigo Suguta, Osaka (JP); Ichiro Kawashima, Osaka (JP); Takeshi Fujita, Osaka (JP)

Correspondence Address: MCDERMOTT WILL & EMERY LLP, 600 13TH STREET, N.W., WASHINGTON, DC, 20005-3096, US

(21) Appl. No.: 11/497,230

(22) Filed: Aug. 2, 2006

(30) Foreign Application Priority Data
Aug. 17, 2005 (JP) JP 2005-236843

(51) Int. Cl. H03G 5/00

(52) U.S. Cl. 381/98

(57) ABSTRACT

In a reproduction section, when the number of detected channels in a decoding section is 2, a bass management judgment section performs control over bass management, so that the bass management is automatically turned OFF.

### BACKGROUND OF THE INVENTION

The present invention relates to digital signal processing techniques in a broad sense, and particularly relates to an audio player for receiving a digital audio signal from the outside, performing various audio processings such as audio decoding and bass decoding, and outputting PCM data to the outside.

In recent years, multi-channel environment for DVD and the like have been widely spread. For example, the number of systems for decoding three or more channel digital audio has been increased. Sound recorded on a DVD is, in general, 5.1 channel digital audio. To correctly decode such 5.1 channel digital audio, five speakers and a bass woofer are needed. Furthermore, each of the five speakers is required to be capable of correctly decoding bass components.

According to a known technique, on the assumption that, for 5.1 channel reproduction, there are not only cases where all of six speakers are connected but also cases where only two of six speakers are connected, an audio output setting is automatically changed according to how many speakers are actually connected in a speaker configuration (see Japanese Laid-Open Publication No. 2003-134591).

In recent years, DVD players have been widely used not only as stationary reproduction equipment for household use but also as a navigation system-type car-mounted player. The same type of LSIs for decoding images and sounds can be commonly used for both of stationary DVD players and car-mounted DVD players. However, because of differences in their applications, different specifications of LSIs for those two types of DVD players are required in many cases.

Equipment having the DVD reproduction function receives not only 5.1 channel digital audio data but also 2 channel digital audio data such as data on a music CD. Therefore, there are cases where control according to the number of channels of the audio data is needed.

Many types of equipment having the function of reproducing DVD have the bass management function of extracting low frequency components in audio data and supplying low frequency components to a sub-woofer. As for car-mounted DVD players, in many cases, an audio processing DSP is connected in a subsequent stage of a decoding LSI and, when a 2-channel digital audio is input, data which does not require bass management or the like is preferably output. Therefore, there are cases where control of turning OFF the bass management function is needed.

Depending on data, the number of channels of audio data to be input is changed while being reproduced. In such a case, full time monitoring during reproduction is necessary. When the number of channels is changed to 2, an OFF control for the bass management function has to be performed.

For the above-described reason, the number of channels of audio data being reproduced has to be monitored at all the time in a system control section of a car-mounted player. Then, if the number of the channels is changed, ON/OFF control for buss management has to be performed.

### SUMMARY OF THE INVENTION

It is therefore an object of the present invention to provide an audio player which can achieve simplification of processing performed in a system control section of an above-described type known car-mounted player and also includes an interface for supplying a common LSI which can be used also in a stationary type player.

To achieve the above-described object, an audio player according to the present invention has the function of automatically turning OFF bass management in a reproduction section when a 2 channel stream is received. Also, the audio player is so configured that selection on whether or not to use an automatic OFF mode is possible.

According to the present invention, an LSI for decoding a video and a sound is so configured to have the function of detecting change in the number of channels and, if a detection result indicates 2 channels, automatically turning OFF the bass management function is provided. Thus, a processing load in a system control section can be reduced. Moreover, with an interface which can specify whether or not to operate the function of automatically turning OFF the bass management function, an LSI which can be commonly used for a stationary type of player and a car-mounted type of player can be provided.

### BRIEF DESCRIPTION OF THE DRAWINGS

FIG. 1 is a block diagram illustrating an exemplary configuration of an audio player according to a first embodiment of the present invention.

FIG. 2 is a flowchart of respective operations of a reproduction section in FIG. 1.

FIG. 3 is a block diagram illustrating an exemplary configuration of an audio player according to a second embodiment of the present invention.

FIG. 4 is a flowchart of respective operations of a reproduction section in FIG. 3.

FIG. 5 is a block diagram illustrating an exemplary configuration of an audio player according to a third embodiment of the present invention.

FIG. 6 is a flowchart of respective operations of a reproduction section in FIG. 5.

### DESCRIPTION OF THE PREFERRED EMBODIMENTS

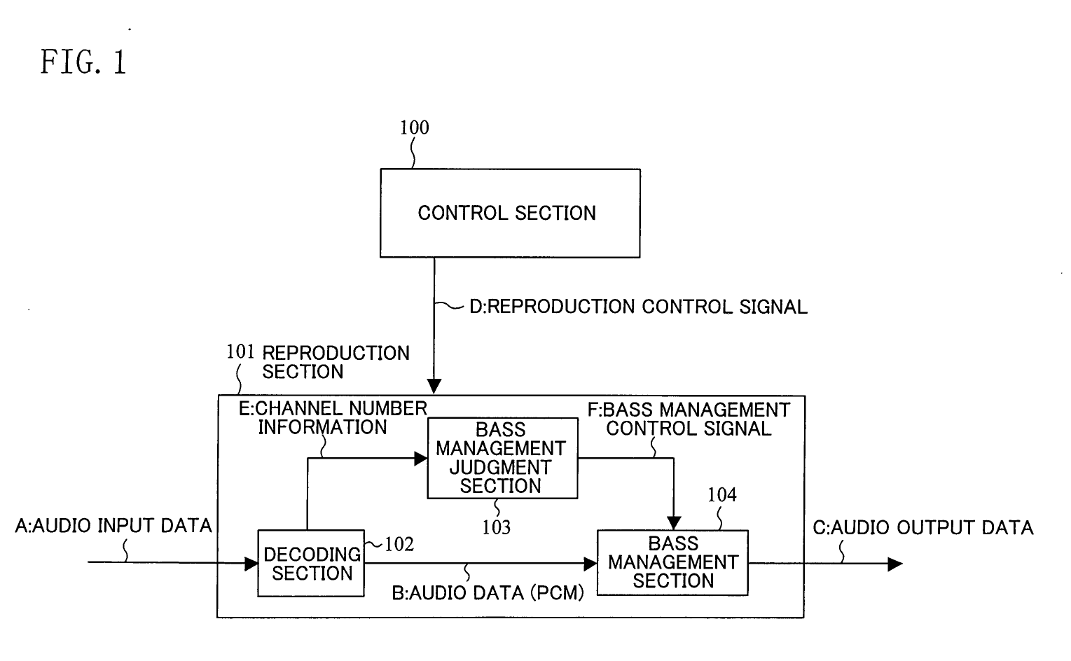

FIG. 1 is a block diagram illustrating an exemplary configuration of an audio player according to a first embodiment of the present invention. The audio player of FIG. 1 includes broadly two parts, i.e., a control section 100 and a reproduction section 101. The reproduction section 101 includes a decoding section 102, a bass management judgment section 103 and a bass management section 104. A denotes audio input data. B denotes decoded audio data. C denotes audio output data. D denotes a reproduction control signal. E denotes channel number information for an input stream. F denotes a bass management control signal.

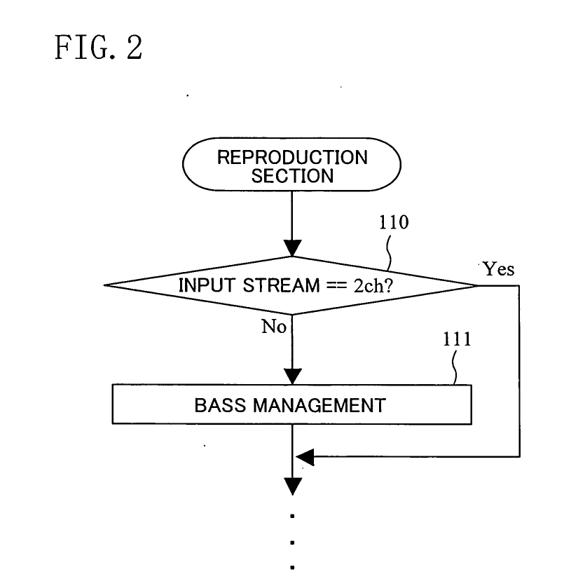

FIG. 2 is a flowchart of respective operations of the reproduction section 101 in FIG. 1. In FIG. 2, 110 denotes input stream judgment and 111 denotes bass management.

The bass management judgment section 103 performs control using the channel number information E detected in the decoding section 102 so that when the channel number information E indicates 2 channels, bass management is not performed in the bass management section 104. Thus, in the control section 100, an ON/OFF operation for bass management according to the channel number becomes unnecessary.

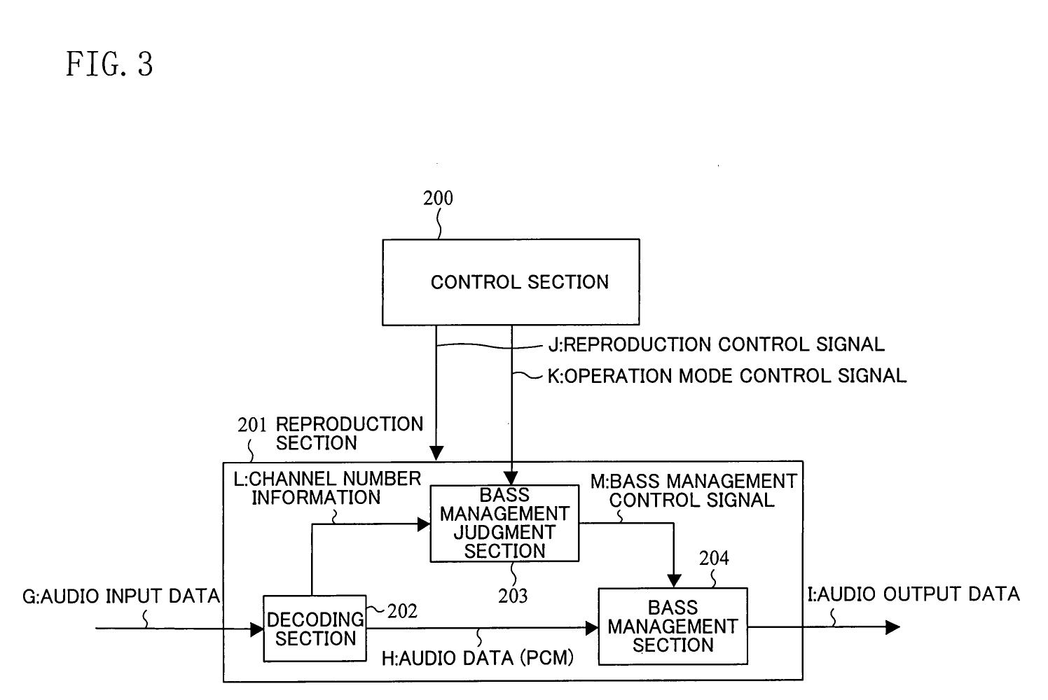

FIG. 3 is a block diagram illustrating an exemplary configuration of an audio player according to a second embodiment of the present invention. The audio player of FIG. 3 includes broadly two parts, i.e., a control section 200 and a reproduction section 201. The reproduction section 201 includes a decoding section 202, a bass management judgment section 203 and a bass management section 204. G denotes audio input data. H denotes decoded audio data. I denotes audio output data. J denotes a reproduction control signal. K denotes an operation mode control signal. L denotes channel number information for an input stream. M denotes a bass management control signal.

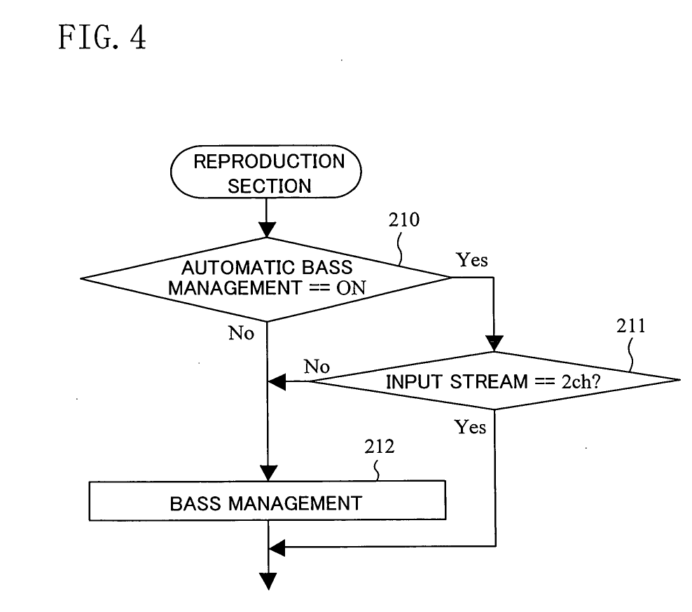

FIG. 4 is a flowchart of respective operations of the reproduction section 201 in FIG. 3. In FIG. 4, 210 denotes bass management automatic mode determination, 211 denotes input stream judgment and 212 denotes bass management.

The bass management judgment section 203 performs control using channel number information L detected in the decoding section 202 so that when the channel number information L indicates 2 channels, the bass management is not performed in the bass management section 204. Thus, in the control section 200, an ON/OFF operation for bass management according to the channel number becomes unnecessary. The audio player further includes an interface capable of setting an operation mode indicating whether or not to automatically perform an ON/OFF operation for bass management in the reproduction section 201 as an operation mode control signal K. This makes the audio player usable also in a system which does not require an automatic ON/OFF operation.

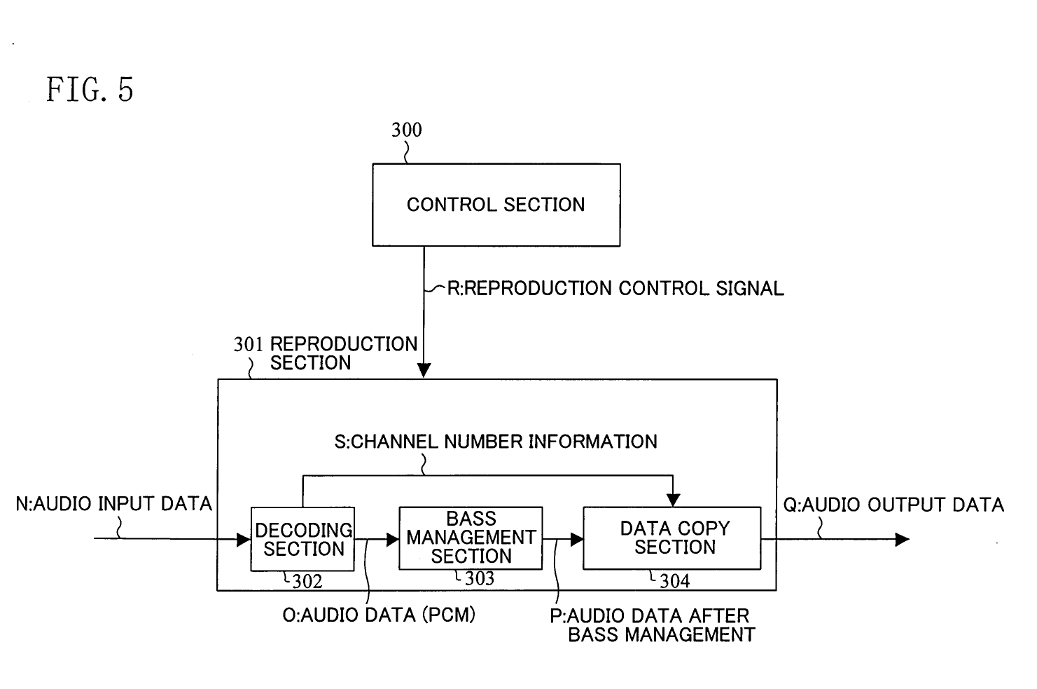

FIG. 5 is a block diagram illustrating an exemplary configuration of an audio player according to a third embodiment of the present invention. The audio player of FIG. 5 includes broadly two parts, i.e., a control section 300 and a reproduction section 301. The reproduction section 301 includes a decoding section 302, a bass management section 303 and a data copy section 304. N denotes audio input data. O denotes decoded audio data. P denotes audio data which has processed through bass management. Q denotes audio output data. R denotes a reproduction control signal. S denotes channel number information of an input stream.

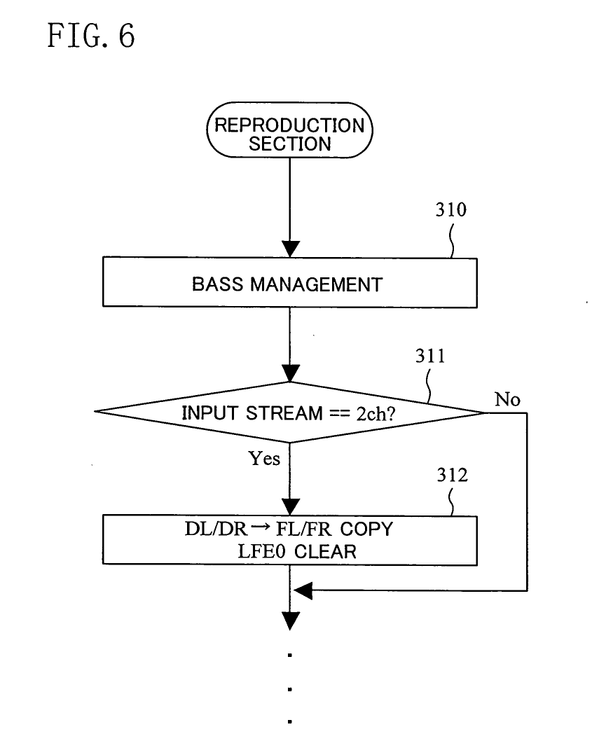

FIG. 6 is a flowchart of respective operations of the reproduction section 301 in FIG. 5. In FIG. 6, 310 denotes bass management, 311 denotes input stream judgment and 312 denotes DL/DR to FL/FR copy and LFE0 clear.

Using the channel number information S detected in the decoding section 302, the data copy section 304 copies data (DL/DR) of downmixed channels to front L/R channels (FL/FR) and performs zero-clear of an LFE channel. Thus, each of the front L channel and the front R channel receives data which has not yet subjected bass management, so that in the control section 300, an ON/OFF operation for bass management according to the number of channels becomes unnecessary.

As has been described, in an audio player according to the present invention, processing performed in a control section when an ON/OFF operation for bass management is performed according to the number of input channels are simplified. Also, the audio player of the present invention includes an interface for determining whether or not to use an automatic ON/OFF function, so that an LSI applicable to players for different applications, such as a stationary player, a car-mounted player and the like can be provided. Therefore, the audio player of the present invention is useful as an audio player having a variety of applications.

What is claimed is:

1. An audio player which has a bass management function of supplying low frequency components of audio data to each channel, the audio player comprising:
a reproduction section; and
a control section for controlling the reproduction section,
wherein the reproduction section includes
a decoding section for decoding an input audio stream,
a bass management section for supplying low frequency components of decoded audio data to each channel, and
a bass management judgment section for judging whether or not to perform bass management, and
wherein the audio player has a function of automatically turning OFF bass management in the reproduction section when the input audio stream is a 2 channel audio signal.

2. The audio player of claim 1, further comprising an interface for making it possible to select whether or not bass management is automatically turned OFF when the input audio stream is a 2 channel audio signal.

3. An audio player which has a bass management function of supplying low frequency components of audio data to each channel, the audio player comprising:
a reproduction section; and
a control section for controlling the reproduction section,
wherein the reproduction section includes
a decoding section for decoding an input audio stream,
a bass management section for supplying low frequency components of decoded audio data to each channel, and
a data copy section for copying data for downmixing output to front L/R channels when the input audio stream is a 2 channel signal.
